(19) United States
(12) Patent Application Publication
(10) Pub. No.: US 2009/0288708 A1
(43) Pub. Date: Nov. 26, 2009

(54) Method for passivating a substrate surface

(75) Inventors: Martin Dinant Bijker, Helmond (NL); Bram Hoex, Tilburg (NL); Wilhelmus Mathijs Marie Kessels, Tilburg (NL); Mauritius Cornelius Maria Van De Sanden, Tilburg (NL)

Correspondence Address: BIRCH STEWART KOLASCH & BIRCH, PO BOX 747, FALLS CHURCH, VA, 22040-0747, US

(73) Assignee: OTB Group B.V., Eindhoven (NL)

(21) Appl. No.: 11/989,628

(22) PCT Filed: Jul. 28, 2006
(86) PCT No.: PCT/NL2006/000393

§ 371 Date: Jun. 26, 2009

(30) Foreign Application Priority Data
Jul. 29, 2005 (NL) 1029647

(51) Int. Cl. H01L 31/04

(52) U.S. Cl. 136/261

(57) ABSTRACT

A method for passivating at least a part of a surface of a semiconductor substrate, wherein at least one layer comprising at least one SiOx layer is realized on said part of the substrate surface by: —placing the substrate (1) in a process chamber (5); —maintaining the pressure in the process chamber (5) at a relatively low value; —maintaining the substrate (1) at a specific substrate treatment temperature; —generating a plasma (P) by means of at least one plasma source (3) mounted on the process chamber (5) at a specific distance (L) from the substrate surface; —contacting at least a part of the plasma (P) generated by each source (3) with the said part of the substrate surface; and —supplying at least one precursor suitable for SiOx realization to the said part of the plasma (P); wherein at least the at least one layer realized on the substrate (1) in subjected to a temperature treatment in a gas environment.

The invention relates to a method for passivating at least a part of a surface of a semiconductor substrate.

Such a method is known from practice. In the known method, a substrate surface of a semiconductor substrate is passivated by realizing a SiOₓ layer, for instance a layer of silicon oxide, on that surface. Here, for instance, use can be made of an oxidation method in an oven. Another known method comprises sputtering the SiOₓ layer. Further, it is known from practice to deposit silicon oxide on a substrate by means of chemical vapor deposition.

The extent of surface passivation is usually expressed by the surface recombination velocity (SRV). A good surface passivation of the semiconductor substrate usually means a relatively low surface recombination velocity.

From the article “Plasma-enhanced chemical-vapor-deposited oxide for low surface recombination velocity and high effective lifetime in silicon”, Chen et al, Journal of Applied Physics 74(4), Aug. 15, 1993, pp. 2856-2859, a method is known in which a low SRV (<2 cm/s) can be obtained with virtually intrinsic silicon substrates, which have relatively high resistivities (>500 Ωcm). In this known method, use is made of a direct plasma enhanced chemical-vapor deposition (PECVD) and a subsequent thermal anneal in a forming gas at preferably 350° C.

Up to now, it has still been found a problem to properly passivate a substrate with a relatively low resistivity, at least such that a relatively low surface recombination velocity can be reached, in particular using deposition of a SiOₓ layer. Such a passivated semiconductor substrate is, for instance, desired for the manufacture of solar cells.

The present invention contemplates obviating above-mentioned drawbacks of the known method. In particular, the invention contemplates a method for passivating a semiconductor substrate, in which a SiOₓ layer obtained with the method has a relatively low surface recombination velocity, while the substrate particularly has a relatively low resistivity.

To this end, the method according to the invention is characterized in that at least one layer comprising at least one SiOₓ layer is realized on above-mentioned part of the substrate surface by:
placing the substrate in a process chamber;
maintaining the pressure in the process chamber at a relatively low value;
maintaining the substrate at a specific substrate treatment temperature suitable for realization of above-mentioned layer;
generating a plasma by means of at least one source mounted on the process chamber at a specific distance from the substrate surface;
contacting at least a part of the plasma generated by each source with the above-mentioned part of the substrate surface; and
supplying at least one precursor suitable for SiOₓ realization to the above-mentioned part of the plasma;

while at least the at least one layer realized on the substrate is subjected to a temperature treatment in a gas environment, while the temperature treatment particularly comprises a forming gas anneal treatment.

It is found that, in this manner, a good surface passivation of the substrate, at least of above-mentioned part of the substrate surface, can be obtained, in particular when the semiconductor substrate inherently has a relatively low resistivity. Preferably, during above-mentioned temperature treatment, at least above-mentioned SiOₓ layer realized on the substrate is maintained at a treatment temperature which is higher than 350° C. It is found that, with such a temperature treatment, particularly good results can be obtained. The treatment temperature may, for instance, be in the range of approximately 250° C.-1000° C., in particular in the range of approximately 500° C.-700° C., more in particular in the range of approximately 550° C.-650° C. The temperature treatment may, for instance, take less than approximately 20 min.

After that temperature treatment, the substrate may, for instance, be cooled, optionally in a forced manner. In addition, preferably, a gas flow is supplied to above-mentioned substrate or at least the SiOₓ layer realized and the substrate during above-mentioned temperature treatment, to provide above-mentioned gas environment. Thus, the temperature treatment may, for instance, comprise a forming gas anneal treatment. The gas environment may, for instance, be provided by supplying a mixture of nitrogen and hydrogen to the substrate and/or the at least one layer realized on the substrate. In that case, the gas environment may, for instance, substantially comprise a hydrogen-nitrogen environment. On the other hand, the gas environment may, for instance, substantially comprise hydrogen gas, for instance by supplying a hydrogen gas flow to the substrate and/or the at least one layer realized on the substrate. The gas or gas mixture then preferably has substantially the same above-mentioned substrate treatment temperature.

According to one aspect of the invention, a method for passivating at least a part of a surface of a semiconductor substrate is characterized in that at least one layer comprising at least one SiOₓ layer is realized on above-mentioned part of the substrate surface by:

placing the substrate in a process chamber;

maintaining the pressure in the process chamber at a relatively low value;

maintaining the substrate at a specific treatment temperature;

generating a plasma by means of at least one source mounted on the process chamber at a specific distance from the substrate surface;

contacting at least a part of the plasma generated by each source with the above-mentioned part of the substrate surface; and

supplying at least one precursor suitable for SiOₓ realization to the above-mentioned part of the plasma;

while then H₂ or a mixture of H₂ with an inert gas, for instance N₂ or Ar, is supplied to above-mentioned plasma, in particular for annealing the at least one layer and/or for increasing the diffusion of H₂ in the at least one layer.

The invention further provides a solar cell, which is provided with at least a part of a substrate at least obtained with a method according to the invention. Such a solar cell can use improved properties in an advantageous manner, for instance a relatively low surface recombination velocity of the substrate surface, which is favorable to the performance of the solar cell.

Further elaborations of the invention are described in the subclaims. The invention will now be elucidated on the basis of a non-limitative exemplary embodiment and with reference to the drawing, in which:

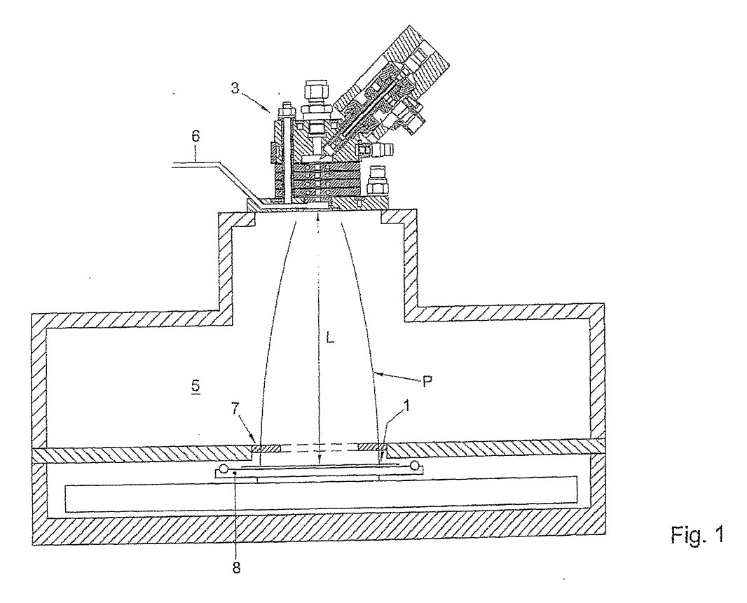

FIG. 1 shows a schematic cross-sectional view of an apparatus for treating a substrate; and

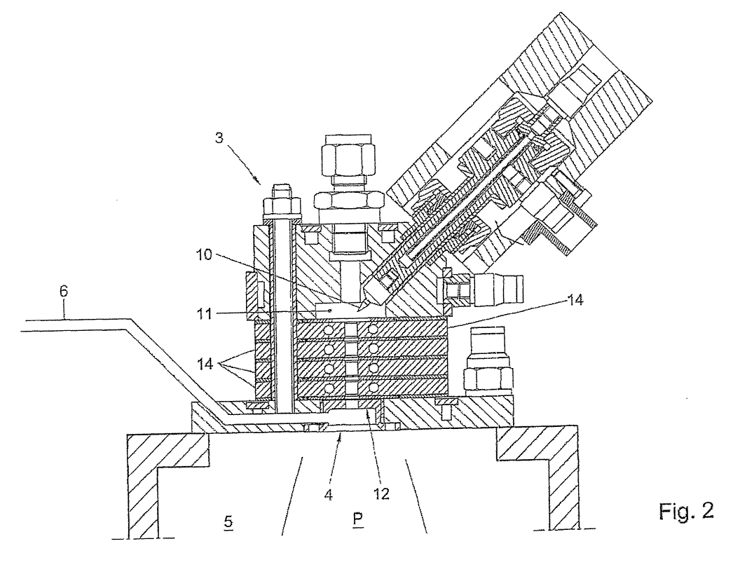

FIG. 2 shows a detail of the cross-sectional view shown in FIG. 1, in which the plasma cascade source is shown.

In this patent application, same or corresponding measures are designated by same or corresponding reference symbols. In the present application, a value provided with a term like “approximately”, “substantially”, “about” or a similar term can be understood as being in a range between that value minus 5% of that value on the one hand and that value plus 5% of that value on the other hand.

FIGS. 1 and 2 show an apparatus with which at least a deposition or realization of at least one SiOₓ layer, and for instance one or more other layers on a substrate can be carried out, in a method according to the invention. The apparatus is, for instance, well suitable for use in an inline process. The apparatus shown in FIGS. 1 and 2 is provided with a process chamber 5 on which a DC (direct current) plasma cascade source 3 is provided. Alternatively, a different type of plasma source may be used. The DC plasma cascade source 3 of the exemplary embodiment is arranged for generating a plasma with DC voltage. The apparatus is provided with a substrate holder 8 for holding one substrate 1 opposite an outflow opening 4 of the plasma source 3 in the process chamber 5. The apparatus further comprises heating means (not shown) for heating the substrate 1 during the treatment.

As shown in FIG. 2, the plasma cascade source 3 is provided with a cathode 10 located in a front chamber 11 and an anode 12 located at a side of the source 3 proximal to the process chamber 5. The front chamber 11 opens into the process chamber 5 via a relatively narrow channel 13 and the above-mentioned plasma outflow opening 4. The apparatus is, for instance, dimensioned such that the distance L between the substrate 1 and the plasma outflow opening 4 is approximately 200 mm-300 mm. Thus, the apparatus can have a relatively compact design. The channel 13 can be bounded by mutually electrically insulated cascade plates 14 and the above-mentioned anode 12. During treatment of a substrate, the process chamber 5 is kept at a relatively low pressure, particularly lower than 5000 Pa, and preferably lower than 500 Pa. Of course, inter alia the treatment pressure and the dimensions of the process chamber need to be such that the growth process can still take place. In practice, with a process chamber of the present exemplary embodiment, the treatment pressure is found to be at least approximately 0.1 mbar for this purpose. The pumping means needed to obtain the above-mentioned treatment pressure are not shown in the drawing. Between the cathode 10 and anode 12 of the source 3, a plasma is generated during use, for instance by ignition of an inert gas, such as argon, which is present therebetween. When the plasma has been generated in the source 3, the pressure in the front chamber 11 is higher than the pressure in the process chamber 5. This pressure can, for instance, be substantially atmospheric and be in the range of 0.5-1.5 bar. Because the pressure in the process chamber 5 is considerably lower than the pressure in the front chamber 6, a part of the generated plasma P expands such that it extends via the relatively narrow channel 7 from the above-mentioned outflow opening 4 into the process chamber 5 for contacting the surface of the substrate 1. The expanding plasma part may, for instance, reach a supersonic velocity.

The apparatus is particularly provided with supply means 6, 7 for supplying flows of suitable treatment fluids to the plasma P in, for instance, the anode plate 12 of the source 3 and/or in the process chamber 5. Such supply means may in themselves be designed in different manners, which will be clear to a skilled person. In the exemplary embodiment, the supply means comprise, for instance, an injector 6 designed for introducing one or more treatment fluids into the plasma P near the plasma source 3. The supply means further comprise, for instance, a shower head 7 for supplying one or more treatment fluids to the plasma P downstream of the above-mentioned plasma outflow opening 4 near the substrate 1. Alternatively, such a shower head 7 is, for instance, arranged near or below the plasma source 3 in the process chamber 5. The apparatus is provided with sources (not shown) which are connected to the above-mentioned supply means 6, 7 via flow control means, for supplying specific desired treatment fluids thereto. In the exemplary embodiment, during use, preferably no reactive gases, such as silane, hydrogen and/or oxygen, are supplied to the plasma in the plasma source 3, so that the source 3 cannot be affected by such gases.

For the purpose of passivating the substrate 1, during use, the cascade source 3 generates a plasma P in the described manner, such that the plasma P contacts the substrate surface of the substrate 1. Flows of treatment fluids suitable for SiOₓ deposition are supplied to the plasma P in a suitable ratio via the supply means 6, 7. The process parameters of the plasma treatment process, at least the above-mentioned process chamber pressure, the substrate temperature, the distance. L between the plasma source 3 and the substrate 1, and the flow rates of the treatment fluids are preferably such that the apparatus deposits the SiOₓ layer on the substrate 1 at an advantageous velocity which is, for instance, in the range of approximately 1-15 nm/s, which, for instance, depends on the velocity of the apparatus.

The above-mentioned substrate temperature, at least during the deposition of SiOₓ, may, for instance, be in the range of 250-550° C., more in particular in the range of 380-420° C.

Above-mentioned treatment fluids may comprise various precursors suitable for SiOₓ deposition. Thus, for instance, D4 and O₂ can be supplied to above-mentioned part of the plasma P, for depositing a SiOₓ layer on the substrate surface, which is found to yield good results. The D4 (also known as octamethyltetrasiloxane) may, for instance, be liquid, and, for instance, be supplied to the plasma via above-mentioned shower head 7. The O₂ may, for instance, be gaseous and be supplied to the plasma via above-mentioned injector 6.

Further, the at least one precursor may, for instance, be selected from the group consisting of: SiH₄, O₂, NO₂, CH₃SiH₃ (1MS), 2(CH₃)SiH₂ (2MS), 3(CH₃)SiH (3MS), siloxanes, hexamethylsiloxane, octamethyltrisiloxane (OMTS), bis(trimethylsiloxy)methylsilane (BTMS), octamethyltetrasiloxane (OMCTS, D4) and TEOS. The precursor may further comprise one or more other substances suitable for SiOₓ.

Since the plasma cascade source operates with DC voltage for generating the plasma, the SiOₓ layer can simply be grown at a constant growth rate, substantially without adjustment during deposition. This is advantageous compared to use of a plasma source driven with AC. Further, with a DC plasma cascade source, a relatively high growth rate can be obtained. It is found that, with this apparatus, a particularly good surface-passivated substrate can be obtained, in particular with a SiOₓ layer, with a relatively low substrate resistivity.

Optionally, on above-mentioned SiOₓ layer, for instance, a SiNₓ may be provided, which may, for instance, form an anti-reflection coating. Further, such a SiNₓ layer may, for instance, supply hydrogen to the deposited SiOₓ layer for the purpose of passivation of the substrate. Preferably, the SiOₓ layer and SiNₓ layer are successively deposited on the substrate 1 by the same deposition apparatus. To this end, for instance, precursors suitable for SiNₓ deposition (for instance NH₃, SiH₄, N₂, and/or other precursors) can be supplied to the plasma P via above-mentioned supply means 6, 7 after deposition of the SiOₓ layer. The layer stack comprising at least one SiOₓ layer and at least one SiNₓ layer is also called a SiOₓ/SiNₓ stack. The thickness of above-mentioned SiNₓ layer is preferably in the range of approximately 25 to 100 nm, and may, for instance, be approximately 80 nm.

Further, for instance, an apparatus may be provided for subjecting the substrate to a temperature treatment after deposition of one or more of above-mentioned layers, for instance to a forming gas anneal treatment in which suitable gases are supplied to the substrate. In this manner, the temperature treatment can be carried out in a gas environment, at least such that at least one surface of the at least one layer realized on the substrate is contacted with those gases. A gas mixture suitable for the temperature treatment is, for instance, a hydrogen-nitrogen mixture. Such a temperature treatment may, for instance, be carried out in a separate thermal treatment apparatus, a separate forming gas anneal apparatus, or the like.

Further, during use of the apparatus, for instance H₂ or a mixture of H₂ and an inert gas such as N₂ or Ar may be supplied to a plasma P, after the at least one layer has been realized on the substrate, for instance for increasing the diffusion of H₂ in the SiOₓ layer or the SiOₓ/SiNₓ stack. Such a plasma treatment may, for instance, be carried out instead of the above-mentioned temperature treatment or in combination with such a temperature treatment.

### EXAMPLE

A silicon oxide (SiO) layer was deposited on a substrate surface of a monocrystalline silicon with a method according to the invention, using an above-described apparatus shown in the Figures. The layer thickness was approximately 100 nm. The substrate inherently had a relatively low resistivity, for instance a resistivity of less than approximately 10 Ωcm. In particular, use was made of an n-doped silicon wafer with a resistivity of 1.4 Ωcm.

In order to deposit the above-mentioned silicon oxide layer on the substrate surface, in this example, use was made of flows of the precursors D4 and O₂. Here, for instance, a D4 flow rate of approximately 5-10 grams per hour was used and a O₂ flow rate of approximately 200 sccm (standard cm⁻³ per minute). The deposition treatment temperature of the substrate was, during the SiOₓ deposition, approximately 400° C.

The deposited silicon oxide layer was optionally provided with a SiNₓ layer, using N₂H₃ and SiH₄, for forming a SiOₓ/SiNₓ stack on the substrate. The SiNₓ layer may, for instance, supply hydrogen to the deposited SiOₓ layer, and also serve as an anti-reflection layer.

After the deposition of above-mentioned layer/layers, the substrate was subjected to a temperature treatment, for instance using a suitable forming gas anneal apparatus. During this temperature treatment, the deposited SiOₓ layer and/or SiNₓ layer was maintained at a treatment temperature of approximately 600° C. for a treatment period of approximately 15 min, and in particular at an atmospheric pressure. In addition, during the temperature treatment, a 90% N₂-10% H₂ gas mixture was supplied to a surface of the SiOₓ layer and/or the SiOₓ/SiNₓ stack for obtaining a forming gas anneal. After above-mentioned approximately 15 min, the substrate and the at least one layer provided thereon were cooled.

The SiOₓ layer or SiOₓ/SiN₂ stack thus obtained was found to have a stable, particularly low surface recombination velocity of approximately 50 cm/s. Therefore, the substrate treated in this manner, which has a very low resistivity, is particularly well suitable for use as, for instance, a ‘building block’ of solar cells.

It goes without saying that various modifications are possible within the framework of the invention as it is set forth in the following claims.

Thus, substrates of various semiconductor materials can be used to be passivated by the method according to the invention.

In addition, the method may, for instance, be carried out using more than one plasma source mounted on a process chamber.

Further, the substrate may, for instance, be loaded into the process chamber 5 from a vacuum environment, such as a load lock brought to a vacuum and mounted to the process chamber. In that case, the pressure in the process chamber 5 can maintain a desired low value during loading. In addition, the substrate may, for instance, be introduced into the process chamber 5 when that chamber 5 is at an atmospheric pressure, while the chamber 5 is then closed and pumped to the desired pressure by the pumping means.

In addition, the plasma source may, for instance, generate a plasma which exclusively contains argon.

Further, for instance, one or more layers can be applied to the substrate, for instance one or more SiOₓ layers and one or more optional other layers such as for instance SiNₓ layers.

Further, preferably, a whole surface of a substrate is passivated by means of a method according to the invention. Alternatively, for instance, only a part of the surface may be passivated by means of the method.

Further, the thickness of the SiOₓ layer realized on the substrate by means of the plasma treatment process may, for instance, be in the range of 10-1000 nm.

Further, a plasma with O₂ as a precursor may, for instance, modify a substrate surface of the substrate, or part of the surface, into SiOₓ, so that above-mentioned SiOₓ layer is realized. In that case, the SiOₓ layer is, in particular, not realized by means of deposition, but by means of modification. The SiOₓ layer may also be realized in a different manner.

1. A method for passivating at least a part of a surface of a semiconductor substrate, wherein at least one layer comprising at least one SiOₓ layer is realized on said part of the substrate surface by:
placing the substrate (1) in a process chamber (5);
maintaining the pressure in the process chamber (5) at a relatively low value;
maintaining the substrate (1) at a specific substrate treatment temperature suitable for realizing said layer;
generating a plasma (P) by means of at least one plasma cascade source (3) mounted on the process chamber (5) at a specific distance (L) from the substrate surface;
contacting at least a part of the plasma (P) generated by each source (3) with the said part of the substrate surface; and
supplying at least one precursor suitable for SiOₓ realization to the said part of the plasma (P);
wherein at least the at least one layer realized on the substrate (1) is subjected to a temperature treatment in a gas environment, wherein the temperature treatment particularly comprises a forming gas anneal treatment.

2. A method according to claim 1, characterized in that, in each plasma cascade source, a DC voltage is used for generating the plasma.

3. A method according to claim 1, wherein, during said temperature treatment, the at least one layer realized on the substrate (1) is maintained at a treatment temperature which is higher than 350° C.

4. A method according to claim 1, wherein said treatment temperature is in the range of approximately 250° C.-1000° C., in particular in the range of approximately 500° C.-700° C., more in particular in the range of approximately 550° C.-650° C., for instance approximately 600° C.

5. A method according to claim 1, wherein said temperature treatment takes less than approximately 20 min.

6. A method according to claim 1, wherein, during said temperature treatment, a gas flow is supplied to said substrate (1) or at least the at least one layer realized on the substrate (1) for providing said gas environment.

7. A method according to claim 1, wherein said gas environment substantially comprises a mixture of nitrogen gas and hydrogen gas.

8. A method according to claim 7, wherein the ratio of nitrogen:hydrogen in said mixture is in the range of approximately 75:25 to 99:1, in particular in the range of approximately 85:15 to 95:5, and is for instance approximately 90:10.

9. A method according to claim 1, wherein said gas environment substantially contains hydrogen gas.

10. A method according to claim 1, wherein the at least one precursor is selected from the group consisting of:
SiH₄
O₂;
NO₂;
CH₃SiH₃ (1MS);
2(CH₃)SiH₂ (2MS);
3(CH₃)SiH (3MS);
siloxanes
hexamethylsiloxane;
octamethyltrisiloxane;
bis(trimethylsiloxy)methylsilane;
octamethyltetrasiloxane (D4); and
TEOS.

11. A method according to claim 1, wherein the substrate (1) inherently has a relatively low resistivity, for instance a resistivity of less than approximately 10 Ωcm, in particular a resistivity of approximately 2 Ωcm or lower.

12. A method according to claim 1, characterized in that the SiOₓ layer is deposited on the substrate (1) at a growth rate which is in the range of approximately 1-15 nm/s.

13. A method according to claim 1, characterized in that the said treatment temperature of the substrate is, at least during the realization of SiOₓ, in the range of 250-550° C., more in particular in the range of 380-420° C.

14. A method according to claim 1, characterized in that the thickness of the SiOₓ layer realized on the substrate (1) by means of the plasma treatment process is in the range of 10-1000 nm.

15. A method according to claim 1, wherein the at least one layer is further provided with at least one SiNₓ layer, wherein the SiNₓ layer is, for instance, realized on said SiOₓ layer, for instance to provide an anti-reflection layer.

16. A method according to claim 17, wherein said SiOₓ layer and SiNₓ layer are successively provided on the substrate (1) by the same apparatus.

17. A method according to claim 17, wherein the thickness of said SiNₓ layer is in the range of approximately 25 to 100 nm, and is in particular approximately 80 nm.

18. A method according to claim 1, wherein the plasma is provided with O₂ as a precursor, such that said substrate surface is modified into SiOₓ for realizing said SiOₓ layer.

19. A method for according to claim 1, wherein at least one layer comprising at least one SiOₓ layer is realized on said part of the substrate surface by:
placing the substrate (1) in a process chamber (5);
maintaining the pressure in the process chamber (5) at a relatively low value;
maintaining the substrate (1) at a specific substrate treatment temperature;
generating a plasma (P) by means of at least one plasma cascade source (3) mounted on the process chamber (5) at a specific distance (L) from the substrate surface;
contacting at least a part of the plasma (P) generated by each source (3) with the said part of the substrate surface; and
supplying at least one precursor suitable for SiOₓ realization to the said part of the plasma (P);
wherein then H₂ or a mixture of H₂ and an inert gas, for instance N₂ or Ar, is supplied to said plasma, in particular for annealing the at least one layer and/or for increasing the diffusion of H₂ in the at least one layer.

20. A solar cell, provided with at least a part of a substrate at least obtained with a method according to claim 1.

21. (canceled)
